(19) United States
(12) Patent Application Publication
(10) Pub. No.: US 2005/0074949 A1
(43) Pub. Date: Apr. 7, 2005

(54) Semiconductor device and a method for fabricating the semiconductor device

(75) Inventors: Sung Mun Jung, Yeoju-kun (KR); Jum Soo Kim, Icheon-city (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 10/954,488

(22) Filed: Oct. 1, 2004

(30) Foreign Application Priority Data
Oct. 1, 2003 (KR) 10-2003-0068498

(51) Int. Cl. H01L 21/336

(52) U.S. Cl. 438/424

(57) ABSTRACT

A method for fabricating the semiconductor device includes forming linear field oxide regions on a semiconductor substrate; forming gate oxide lines on the semiconductor substrate between the field oxide regions; and forming gate lines on the field oxide regions and the gate oxide lines, the gate lines being substantially perpendicular to the field oxide regions, wherein forming the gate lines also includes forming recesses in the semiconductor substrate between the gate lines, the recesses exposing portions of the semiconductor substrate.

### RELATED APPLICATION

This application is related to and claims priority to Korean Patent Application No. 10-2003-0068498, filed on Oct. 1, 2003, the entire contents of which are incorporated herein as a reference.

### BACKGROUND

(a) Technical Field

The present invention relates to a method for fabricating a semiconductor device and, in particular, to a method for decreasing the height difference between a field oxide region and an active region so as to reduce self-aligned source (SAS) resistance at a cell region.

(b) Description of the Related Art

Recently, with the wide applications of flash memories and growing competition in price thereof, various technologies have been developed to reduce the sizes of the memory devices. One such technology is a self-aligned source (SAS) technique.

The SAS technique is a method for reducing the cell size in a bit line direction and was described in U.S. Pat. No. 5,120,671. The SAS technique is essentially adopted for below−0.25 μm line width technology. Because the SAS technology can reduce a gap between the gate and the source of a transistor, the size of a memory cell can be reduced by about 20% with the introduction of the SAS technique.

However, the conventional SAS technique has a drawback in that junction resistance of the source per cell dramatically increases because the SAS region is formed along a trench profile.

Moreover, the SAS technique has another drawback in that the resistivity at a sidewall of a trench, which is a boundary region between the trench region and an active region, is much greater than and may be about 10 times as much as that at the horizontal surfaces of the trench, because the depth and amount of the implantation of the impurity ions in the sidewall are smaller than those in the other regions, such as the horizontal surfaces of the trench and the active regions.

### SUMMARY

It is therefore desirable to address the above problem and to provide a method for fabricating a semiconductor device, which is capable of reducing the resistance generated from adopting the SAS technique.

It is also desirable to provide a method for fabricating a semiconductor device, which is capable of reducing the resistance at the sidewall of the SAS region.

Consistent with an embodiment of the present invention, there is provided a semiconductor device that includes linear field oxide regions on a semiconductor substrate; gate oxide lines on active regions of the semiconductor substrate between the field oxide regions; gate lines on the field oxide regions and the gate oxide lines, the gate lines being substantially perpendicular to the field oxide regions; and recesses in the semiconductor substrate below portions of the gate oxide lines between the gate lines, the recesses exposing portions of the semiconductor substrate.

Consistent with the present invention, there is also provided a method for fabricating a semiconductor device that includes forming linear field oxide regions on a semiconductor substrate; forming gate oxide lines on the semiconductor substrate between the field oxide regions; and forming gate lines on the field oxide regions and the gate oxide lines, the gate lines being substantially perpendicular to the field oxide regions, wherein forming the gate lines also includes forming recesses in the semiconductor substrate between the gate lines, the recesses exposing portions of the semiconductor substrate.

Consistent with the present invention, there is further provided a method for fabricating a semiconductor device that includes forming linear field oxide regions on a semiconductor substrate; forming gate oxide lines on the semiconductor substrate between the field oxide regions; forming first gate lines on the field oxide regions and the gate oxide lines, the first gate lines being substantially perpendicular to the field oxide regions and having openingsexposing the gate oxide lines; forming a dielectric layer over the first gate lines; and forming second gate lines on the dielectric layer and the field oxide regions, the second gate lines being substantially perpendicular to the field oxide regions, wherein forming the second gate lines also includes forming recesses in the semiconductor substrate between the gate lines, the recesses exposing portions of the semiconductor substrate.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1A is a plan view illustrating a conventional memory cell without the SAS technique;

FIG. 1B is a plan view illustrating a memory cell fabricated with the SAS technique;

FIG. 1C is a cross sectional view of a portion of the memory cell of FIG. 1B taken along line I-I′;

FIGS. 1D and 1E are cross sectional views illustrating a process of forming gate lines of the memory device of FIG. 1B taken along line II-II′ as shown in FIG. 1B;

FIG. 1F is a plan view of a mask used for forming the gate lines of the memory device of FIG. 1B;

FIG. 2 is a plan view of a memory device consistent with an embodiment of the present invention;

FIGS. 3A and 3B illustrate cross-sectional views of the memory device of FIG. 2 along line III-III′ during a manufacturing process thereof;

FIG. 4 is a plan view of a mask pattern used during the manufacturing process of the memory device of FIG. 2; and

FIG. 5 is a cross sectional view of a portion of the memory device of FIG. 2 along line IV-IV′.

### DETAILED DESCRIPTION OF THE PREFERRED EMBODIMENTS

Reference will now be made in detail to exemplary embodiments of the invention, examples of which are illustrated in the accompanying drawings. Wherever possible, the same reference numbers will be used throughout the drawings to refer to the same or like parts.

The SAS technique is a technology for reducing the size of a memory cell in a bit line direction by decreasing a gap between a gate and a source of transistors. The SAS technique is an essential process for devices with a below−0.25 μm line width.

Typically, a NOR type flash memory utilizes a common source and one source contact is formed per 16 memory cells.

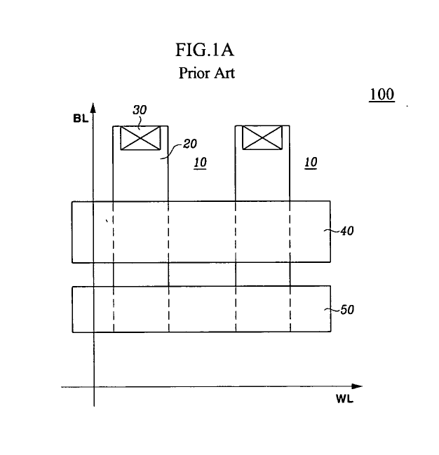

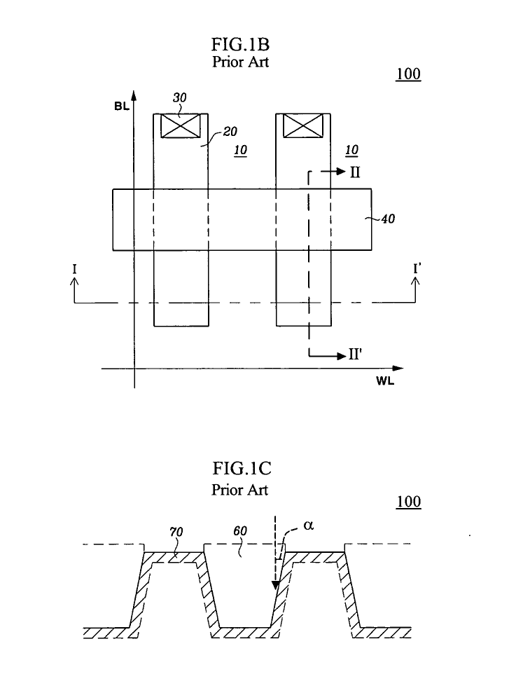

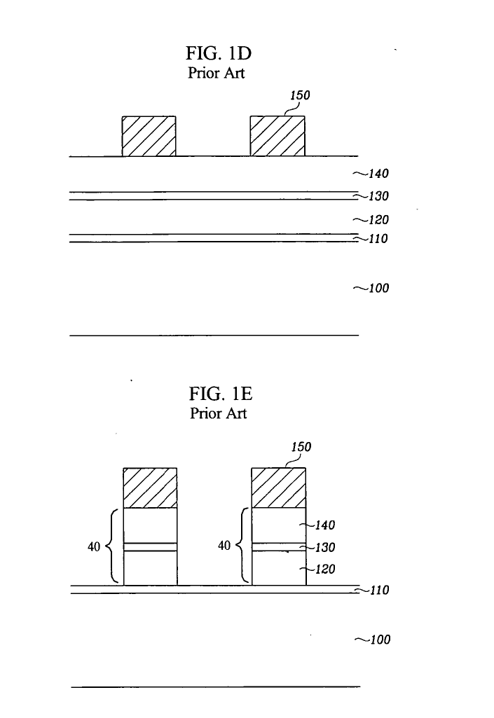

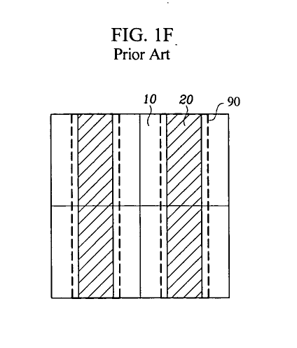

FIG. 1A is a plan view illustrating a conventional memory cell 100 without using the SAS technique, FIG. 1B is a plan view illustrating memory cell 100 fabricated with the SAS technique, and FIG. 1C is a cross sectional view of a portion of memory cell 100 taken along line I-I′ in FIG. 1B.

In FIG. 1A, field oxide regions 10 as device isolation regions are formed in a semiconductor substrate (not numbered) in a bit line (BL) direction, and active regions 20 in which devices are formed are defined between field oxide regions 10. A drain contact 30 is formed at each cell formed in the active region 20.

A plurality of gate lines 40 are formed in a word line (WL) direction, and a plurality of common source lines 50 are formed in parallel with the gate line 40 at a predetermined distance therefrom. Only one gate line 40 and one common source line 50 are shown in FIG. 1A.

As shown in FIG. 1B and FIG. 1C, by introducing the SAS technique for forming memory cell 1, an SAS region 70 is formed by injecting impurity ions in a common source region which corresponds to common source line 50 after etching a plurality of field oxide trenches 60 in the semiconductor substrate. Oxide is then deposited in field oxide trenches 60 to form field oxide regions 10.

FIGS. 1D and 1E are cross sectional views along line II-II′ of FIG. 1B illustrating a process of forming gate lines 40, wherein two gate lines 40 are shown. FIG. 1F is a plan view of a mask used for forming gate lines 40.

In FIGS. 1D and 1E, it is assumed that memory cell 100 is a flash memory cell and that each of gate lines 40 comprises a first polycrystalline silicon (polysilicon) layer acting as a floating gate, a dielectric layer such as a stacking structure of oxide-nitride-oxide (ONO) layer, and a second polysilicon. Referring to FIG. 1D, a gate oxide layer such as tunneling oxide layer 110, a first polysilicon layer 120 acting as a floating gate, a dielectric layer 130, and a second polysilicon layer 140 are sequentially formed on a semiconductor substrate 100. A photoresist pattern 150 for forming gate lines 40 is formed on second polysilicon 140. Optionally, mask pattern 90 as shown in FIG. 1F may be used to pattern first polysilicon 120 prior to the deposition of dielectric layer 130.

Next, with reference to FIG. 1E, second polysilicon layer 140, dielectric layer 130, and first polysilicon layer 120 are etched using photoresist pattern 150 as a mask. Accordingly, a plurality of gate lines 40 are formed.

Because SAS region 70 (FIG. 1C) is formed along the trench profile of trenches 60 and because the actual junction resistance is proportional to a surface length of the SAS region 70, the actual junction resistance of the source per cell increases dramatically.

Also, because the depth and amount of the implantation of the impurity ions in the sidewalls of trenches 60 are smaller than those in the other regions, such as the horizontal surfaces of trenches 60 and active regions 20, the resistivity of the sidewalls in trenches 60 is much greater than the resistivity in the other regions. Particularly, when injecting impurity ions for forming SAS region 70, impurity ions are injected with a tilt angle a into the sidewalls of trenches 60 and, therefore, the injection energy and the amount of impurity ions injected into each sidewall are less than those onto the horizontal surfaces of trenches 60 and active regions 20, and are proportional to sine α. Typically, the resistivity at the sidewall portions are about 10 times greater than that at the other surfaces such as the horizontal surfaces of trenches 60 and active region 20.

Consistent with an embodiment of the present invention, a height of an active region of a memory device is reduced to decrease a height difference between a field oxide region and the active region.

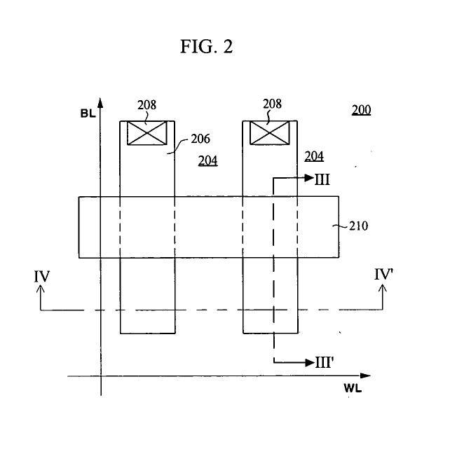

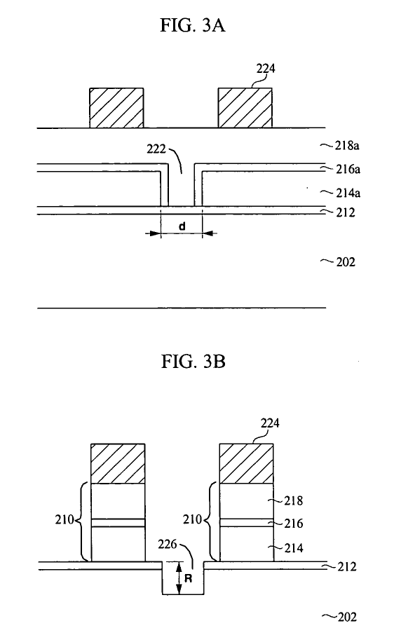

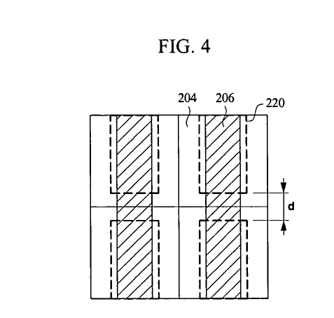

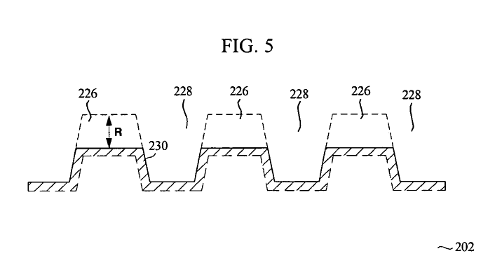

A memory device consistent with an embodiment of the present invention and the method thereof may be described with reference to FIGS. 2-4, wherein FIG. 2 is a plan view of a memory device 200, FIGS. 3A and 3B illustrate cross-sectional views of memory device 200 along line III-III′ in FIG. 2 during a manufacturing process of memory device 200, FIG. 4 is a plan view of a mask pattern used during the manufacturing process of memory device 200, and FIG. 5 is a cross sectional view of a portion of memory device 200 along line IV-IV′ in FIG. 2, wherein only active regions and field oxide regions of memory device 200 are shown in FIG. 5.

Referring to FIG. 2 and FIGS. 3A-3B, a memory device 200 consistent with the embodiment of the present invention includes a plurality of field oxide regions 204 formed in a semiconductor substrate 202 for defining a plurality of active regions 206. Memory cells (not shown) are formed in active regions 206 and drain contacts 208 for providing contacts to the memory cells are shown in FIG. 2. A plurality of gate lines 210 (only one of which is shown in FIG. 2) are formed over the semiconductor substrate. Also as shown in FIG. 3B, each gate line 210 is isolated from semiconductor substrate 202 by gate oxide layer 212 and comprises a floating gate 214, a dielectric layer 216, and a control gate 218.

A method for fabricating semiconductor device 200 consistent with the present invention will be described in detail.

First, linear trench lines, i.e., field oxide regions 204, are formed on semiconductor substrate 202 by etching a plurality of trenches in parallel with a bit line direction.

Next, after an oxide is filled in the trench, gate oxide lines 212 are formed on the semiconductor substrate between the trench lines.

Next, gate lines 210 are formed on the trench lines and the gate oxide lines in a direction perpendicular to the trench lines, i.e., in parallel with a word line direction. Gate lines 210 are formed as follows. First, a first polysilicon layer 214a is formed by depositing and etching a layer of polysilicon.

A mask pattern 220 as shown in FIG. 4 is used to etch the first polysilicon to form first polysilicon layer 214a. As shown in FIG. 4, mask pattern 220 includes openings (only one of which is shown in FIG. 4) having a width d. Accordingly, first polysilicon gate lines 214a have the same pattern as mask pattern 220 and, as shown in FIG. 3A, first polysilicon gate lines 214a are formed with openings 222 (only one of which is shown in FIG. 3A), exposing portions of gate oxide 212 on a portion of active region 206 where a source line of memory device 200 is to be formed, as shown in FIG. 3A. Second, a dielectric layer 216a such as an ONO multilayer is deposited, followed by the deposition of a second polysilicon layer 218a. Then, a photoresist pattern 224 in parallel to the word line direction is used to sequentially etch second polysilicon layer 218a, ONO layer 216a, and first polysilicon layer 214a to form gate lines 210. Then, gate oxide layer 212 and semiconductor substrate 202 are further etched to form a plurality of recesses 226 (only one of which is shown in FIG. 3B) in a common source region of semiconductor substrate 202, as shown in FIG. 3B. FIG. 3B also indicates that recesses 226 have a depth R.

Then, as shown in FIG. 5, after gate lines 210 are formed, the oxide in portions of the trench lines, i.e., field oxide regions 204 in the common source region located between gate lines 210, is etched away, forming a plurality of cavities 228 in the trench lines. Impurity ions are then injected into semiconductor substrate 202 exposed through recesses 226 and cavities 228 to form a SAS region 230.

Because recesses 226 (FIGS. 3B and 5), which expose portions of semiconductor substrate 202 below gate oxide 212 between gate lines 210, are formed and have a depth R, the height of the top of SAS region 230 becomes lower by R, as compared to SAS region 70 of conventional memory device 100 as shown in FIG. 1C, provided other conditions are the same. Accordingly, the resistance of SAS region 230 becomes lower.

The depth R of recesses 226 may be adjusted and may depend on the depth of cavities 228. In one aspect, R is equal to or less than the depth of cavities 228. For example, the cavities are formed to have a depth of 1500˜4000 Å measured from the upper surface of semiconductor substrate 202, and recesses 226 may have a depth of 500˜2500 Å measured from the upper surface of semiconductor substrate 202.

Also, in an aspect of the embodiment of the present invention, the first polysilicon 214 has a thickness of 600˜2500 Å.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A semiconductor device, comprising:
linear field oxide regions formed on a semiconductor substrate;
gate oxide lines formed on active regions of the semiconductor substrate between the field oxide regions;
gate lines formed on the field oxide regions and the gate oxide lines, the gate lines being substantially perpendicular to the field oxide regions; and
recesses in the semiconductor substrate below portions of the gate oxide lines between the gate lines, the recesses exposing portions of the semiconductor substrate.

2. The device of claim 1, wherein the recesses have a depth of 500˜2500 Å measured from an upper surface of the semiconductor substrate.

3. The device of claim 1, wherein the field oxide regions include a trench having a depth of 1500˜4000 Å measured from an upper surface of the semiconductor substrate.

4. The device of claim 1, wherein the gate lines have a thickness of 600˜2500 Å.

5. The device of claim 1, wherein the gate lines comprise a first polycrystalline silicon layer, a dielectric layer, and a second polycrystalline silicon layer.

6. The device of claim 5, wherein the dielectric layer includes a stacking structure of oxide layer—nitride layer—oxide layer.

7. The device of claim 1, further comprising:
cavities formed by removing portions of the field oxide regions between the gate lines; and
a self-aligned source (SAS) region in the semiconductor substrate exposed through the recesses and cavities, wherein the self-aligned source region is formed by injecting impurity ions.

8. The device of claim 1, wherein the field oxide regions are substantially parallel to a bit line of the device, and the gate lines are substantially parallel to a word line of the device.

9. A method for fabricating a semiconductor device, comprising:
forming linear field oxide regions on a semiconductor substrate;
forming gate oxide lines on the semiconductor substrate between the field oxide regions; and
forming gate lines on the field oxide regions and the gate oxide lines, the gate lines being substantially perpendicular to the field oxide regions, wherein forming the gate lines also include forming recesses in the semiconductor substrate between the gate lines, the recesses exposing portions of the semiconductor substrate.

10. The method of claim 9, wherein the recesses have a depth of 500˜2500 Å measured from an upper surface of the semiconductor substrate.

11. The method of claim 9, wherein the field oxide regions have a depth of 1500˜4000 Å measured from an upper surface of the semiconductor substrate.

12. The method of claim 9, wherein the gate lines have a thickness of 600˜2500 Å.

13. The method of claim 9, further comprising:
etching portions of the field oxide regions between the gate lines to form cavities, after forming the gate lines; and
forming a self-aligned source (SAS) region by injecting impurity ions into the semiconductor substrate exposed through the recesses and cavities.

14. The method of claim 9, wherein the field oxide regions are substantially parallel to a bit line of the device, and the gate lines are substantially parallel to a word line of the device.

15. A method for fabricating a semiconductor device, comprising:
forming linear field oxide regions on a semiconductor substrate;
forming gate oxide lines on the semiconductor substrate between the field oxide regions;
forming first gate lines on the field oxide regions and the gate oxide lines, the first gate lines being substantially perpendicular to the field oxide regions and having openings exposing the gate oxide lines;
forming a dielectric layer over the first gate lines; and
forming second gate lines on the dielectric layer and the field oxide regions, the second gate lines being substantially perpendicular to the field oxide regions, wherein forming the second gate lines also includes forming recesses in the semiconductor substrate between the gate lines, the recesses exposing portions of the semiconductor substrate.

16. The method of claim 15, wherein the dielectric layer includes a stacking structure of oxide layer—nitride layer—oxide layer.

17. The method of claim 15, wherein the recesses have a depth of 500˜2500 Å measured from an upper surface of the semiconductor substrate.

18. The method of claim 15, wherein the field oxide regions have a depth of 1500˜4000 Å measured from the upper surface of the semiconductor substrate.

19. The method of claim 15, wherein the gate lines have a thickness of 600˜2500 Å.

20. The method of claim 15, further comprising:
etching portions of the field oxide regions between the first gate lines to form cavities, after forming the second gate lines; and
forming a self-aligned source (SAS) region by injecting impurity ions into the semiconductor substrate exposed through the recesses and cavities.

21. The method of claim 15, wherein the field oxide regions are substantially parallel to a bit line of the device, and the gate lines are substantially parallel to a word line of the device.
